(19) United States
(12) Patent Application Publication
(10) Pub. No.: US 2026/0102734 A1
(43) Pub. Date: Apr. 16, 2026

(54) HEAT AND MASS EXCHANGER ASSEMBLIES

(71) Applicant: BLUE FRONTIER, INC., Boca Raton, FL (US)

(72) Inventors: Daniel A. BETTS, Parkland, FL (US); Matthew TILGHMAN, Pennington, NJ (US); Zachary HANDEL, Jupiter, FL (US)

(73) Assignee: BLUE FRONTIER, INC., Boca Raton, FL (US)

(21) Appl. No.: 19/356,730

(22) Filed: Oct. 13, 2025

Related U.S. Application Data
(60) Provisional application No. 63/707,068, filed on Oct. 14, 2024.

(51) Int. Cl. B01D 53/14; B01D 53/18; B01D 53/26; H05K 7/20

(52) U.S. Cl. CPC B01D 53/1425; B01D 53/18; B01D 53/263; H05K 7/20745; B01D 2257/80; B01D 2279/50

(57) ABSTRACT

The disclosure relates to heat-mass exchangers. In some examples, a heat-mass exchanger includes a housing configured to receive a flow of supply air cooled and dehumidified by a liquid desiccant conditioner system. The heat-mass exchanger also includes a header configured to receive low concentration liquid desiccant from the liquid desiccant conditioner system, and feed the low concentration liquid desiccant onto one or more heat transfer tubes within the housing. The one or more heat transfer tubes are configured to dissipate heat to the liquid desiccant to generate relatively higher concentration desiccant. Further, the heat-mass exchanger includes a collector that is configured to capture the higher concentration desiccant, and feed the higher concentration desiccant to the liquid desiccant conditioner system.

### CROSS-REFERENCE TO RELATED APPLICATIONS

This application claims priority under 35 U.S.C. § 119(e) to United States Application No. 63/707,068, filed on Oct. 14, 2024, the entire contents of which are incorporated herein by reference.

### TECHNICAL FIELD

The disclosure relates generally to heat exchangers for heating, ventilation, and air conditioning (HVAC) systems.

### BACKGROUND

Heating, ventilation, and air conditioning (HVAC) systems generally cool ambient or room temperature air using a vapor compression refrigeration cycle. The HVAC systems may cool the ambient or room temperature air by removing heat using a refrigerant. Further, the HVAC systems may include a heat exchanger that operates to remove the heat from the refrigerant. For example, the heat exchanger may include plates or coils through which the refrigerant flows. A fan may blow air across the plates or coils to cool the refrigerant flowing within. Less frequently, the HVAC systems may employ a liquid desiccant to dehumidify the air during the cooling process.

### SUMMARY

In one aspect, a heat-mass exchanger is provided that includes a housing configured to receive a flow of supply air cooled and dehumidified by a liquid desiccant conditioner system; a header configured to feed desiccant onto at least one heat transfer tube within the housing, the at least one heat transfer tube configured to dissipate heat to the desiccant to generate relatively higher concentration desiccant; and a collector configured to capture the higher concentration desiccant and feed the higher concentration desiccant to the liquid desiccant conditioner system.

In another aspect, a data center cooling system is provided that includes a liquid desiccant conditioning system; and a heat-mass exchanger. The heat-mass exchanger includes a housing configured to receive a flow of supply air from the liquid desiccant conditioner system; a header configured to receive desiccant from the liquid desiccant conditioner system and feed the desiccant onto at least one heat transfer tube within the housing, the at least heat transfer tube configured to dissipate heat to the desiccant to generate relatively higher concentration desiccant; and a collector configured to capture the higher concentration desiccant and feed the higher concentration desiccant to the liquid desiccant conditioner system to dehumidify a flow of outside air.

In still another aspect, a heat-mass exchanger is provided that includes a housing configured to receive a flow of supply air cooled and dehumidified by a liquid desiccant conditioner system; a first header configured to feed desiccant onto at least a first heat transfer tube within the housing, the at least first heat transfer tube configured to dissipate heat to the desiccant to generate relatively higher concentration desiccant; a collector configured to capture the higher concentration desiccant and feed the higher concentration desiccant to the liquid desiccant conditioner system; and a second header configured to feed water onto at least a second heat transfer tube within the housing.

### BRIEF DESCRIPTION OF THE DRAWINGS

The following drawings are illustrative of particular embodiments of the present disclosure and therefore do not limit the scope of the present disclosure. The drawings are not to scale and are intended for use in conjunction with the explanations in the following detailed description.

FIG. 1 illustrates a heat exchanging system, in accordance with some embodiments.

FIG. 2 illustrates portions of a heat exchanging system, in accordance with some embodiments.

FIG. 3 illustrates a heat transfer tube, in accordance with some embodiments;

FIG. 4 illustrates a heat transfer tube, in accordance with some embodiments.

FIG. 5 illustrates portions of a heat exchanger, in accordance with some embodiments.

FIG. 6 illustrates portions of a heat exchanger, in accordance with some embodiments.

FIG. 7A illustrates portions of a heat exchanging system, in accordance with some embodiments.

FIG. 7B illustrates portions of a heat exchanging system, in accordance with some embodiments.

FIG. 7C illustrates portions of a heat exchanging system, in accordance with some embodiments.

FIG. 8A illustrates portions of a heat exchanger, in accordance with some embodiments.

FIG. 8B illustrates a rectangular heat transfer tube, in accordance with some embodiments.

FIG. 8C illustrates portions of a heat exchanger, in accordance with some embodiments.

FIG. 9A illustrates a header of a heat exchanger, in accordance with some embodiments.

FIG. 9B illustrates another view of the header of FIG. 9A, in accordance with some embodiments.

FIG. 10 illustrates portions of a heat exchanging system, in accordance with some embodiments.

### DETAILED DESCRIPTION

The following discussion omits or only briefly describes conventional features of heat and mass exchangers that are apparent to those skilled in the art. It is noted that various embodiments are described in detail with reference to the drawings, in which like reference numerals represent like parts and assemblies throughout the several views. Reference to various embodiments does not limit the scope of the claims attached hereto. Additionally, any examples set forth in this specification are intended to be non-limiting and merely set forth some of the many possible embodiments for the appended claims. Further, particular features described herein can be used in combination with other described features in each of the various possible combinations and permutations.

Unless otherwise specifically defined herein, all terms are to be given their broadest reasonable interpretation including meanings implied from the specification as well as meanings understood by those skilled in the art and/or as defined in dictionaries, treatises, etc. It must also be noted that, as used in the specification and the appended claims, the singular forms “a,” “an” and “the” include plural referents unless otherwise specified, and that the terms “includes” and/or “including,” when used in this specification, specify the presence of stated features, elements, and/or components, but do not preclude the presence or addition of one or more other features, steps, operations, elements, components, and/or groups thereof. In the description, relative terms such as “horizontal,” “vertical,” “up,” “down,” “top,” and “bottom” as well as derivatives thereof (e.g., “horizontally,” “downwardly,” “upwardly,” etc.) should be construed to refer to the orientation as then described or as shown in the drawing figure under discussion. These relative terms are for convenience of description and normally are not intended to require a particular orientation. Terms including “above” versus “below,” “inwardly” versus “outwardly,” “longitudinal” versus “lateral,” and the like are to be interpreted relative to one another or relative to an axis of elongation, or an axis or center of rotation, as appropriate. Terms concerning attachments, coupling, and the like, such as “connected” and “interconnected,” refer to a relationship wherein structures are secured or attached to one another either directly or indirectly through intervening structures, as well as both movable or rigid attachments or relationships, unless expressly described otherwise. The terms “operatively connected,” “operably connected,” and the like are such attachments, couplings, or connections that allow the pertinent structures to operate as intended by virtue of that relationship.

Embodiments of the present disclosure relate generally to heat and mass exchangers (also referred to herein as “heat exchangers”) and, more particularly, to heat and mass exchangers for liquid desiccant conditioning systems that can extract heat from heat transfer tubes, such as heat transfer tubes from a data center.

In some examples, a heat and mass exchanger includes a housing, at least one header, and at least one collector. One or more heat transfer tubes, such as heat pipes, may enter the housing. For example, the one or more heat transfer tubes may be coupled to a data center, and may be configured to deliver heat generated by the data center (e.g., heat generated by processors of the data center). Further, the housing is configured to receive a flow of supply air that is cooled and dehumidified by a liquid desiccant conditioner system, and to provide the flow of supply air across the one or more heat transfer tubes. In addition, the header is configured to feed liquid desiccant onto at least one heat transfer tube within the housing. For instance, the header may receive low concentration liquid desiccant from the liquid desiccant conditioner system, and may flow the low concentration liquid desiccant onto evaporative media or, in some examples, an uppermost heat transfer tube.

The heat transfer tube may dissipate heat (e.g., heat from the data center) to the low concentration liquid desiccant. The dissipated heat may cause the low concentration liquid desiccant to evaporate water, thereby generating relatively higher concentration liquid desiccant. In some examples with more than one heat transfer tube, the liquid desiccant may flow (e.g., fall, roll off) through evaporative media from one or more higher heat transfer tubes to one or more lower heat transfer tubes. Additionally, the collector is configured to capture the higher concentration desiccant, and feed the higher concentration desiccant to the liquid desiccant conditioner system. For instance, the collector may be positioned underneath the heat transfer tubes. The relatively higher concentration liquid desiccant may fall from one or more of the heat transfer tubes and into the collector. The collector may then feed the relatively higher concentration liquid desiccant to the liquid desiccant conditioner system to be used to, for example, dehumidify a flow of process air (e.g., the flow of air entering the liquid desiccant conditioner system for conditioning). At least a portion (e.g., all) of the dehumidified flow of process air leaving the conditioner can be fed into the heat and mass exchanger to flow across the one or more heat transfer tubes, as described herein.

In some examples, metal fins, such as aluminum fins, are positioned within the housing and across one or more of the heat transfer tubes. The metal fins can increase the surface area of the mass transfer contact area of the heat transfer tubes. For instance, the header may flow the low concentration liquid desiccant onto the metal fins, which are in contact with the heat transfer tubes. As such, the metal fins may absorb heat from the heat transfer tubes, and dissipate the absorbed heat to the low concentration liquid desiccant dripping onto the metal fins.

In some examples, the heat transfer tubes, at least within the housing, are positioned in one or more columns, where each column includes at least two heat transfer tubes vertically offset from each other. In some instances, one or more of the heat transfer tubes are cylindrical in shape. In other instances, at least one heat transfer tube is rectangular in shape, and at least another heat transfer tube is cylindrical in shape. For instance, for a given column, an uppermost heat transfer tube may be rectangular in shape, while any other heat transfer tube for the column may be circular in shape.

In some examples, evaporative media, such as sponge material, is positioned between vertically offset heat transfer tubes. The evaporative material may promote the evaporation of water from the liquid desiccant, thereby increasing the moisture removal rate of the liquid desiccant.

In some examples, at least one header receives water in addition to, or alternate to, receiving low concentration liquid desiccant from the liquid desiccant conditioner system. For instance, the water may be condensate captured by the liquid desiccant conditioner system during cooling of a flow of process air. In some examples, the header drips the water onto at least one heat transfer tube. For instance, in some examples, the header drips low concentration liquid desiccant onto a first number of columns of the heat transfer tubes, and drips water onto a second number of columns of the heat transfer tubes. The housing may be configured to divert the flow of supply air across the first number of columns of the heat transfer tubes and then across the second number of columns of the heat transfer tubes.

In some examples, the heat and mass exchanger applies a jet impingement cooling process that increases heat transfer rates from one or more heat transfer tubes to the low concentration liquid desiccant. For instance, a header may include one or more nozzles (e.g., high-pressure nozzles) that are configured to provide a jet of the low concentration liquid desiccant onto a heat transfer tube. The jet of low concentration liquid desiccant provided by each nozzle can increase convective heat transfer between the heat transfer tube and the jetted low concentration liquid desiccant.

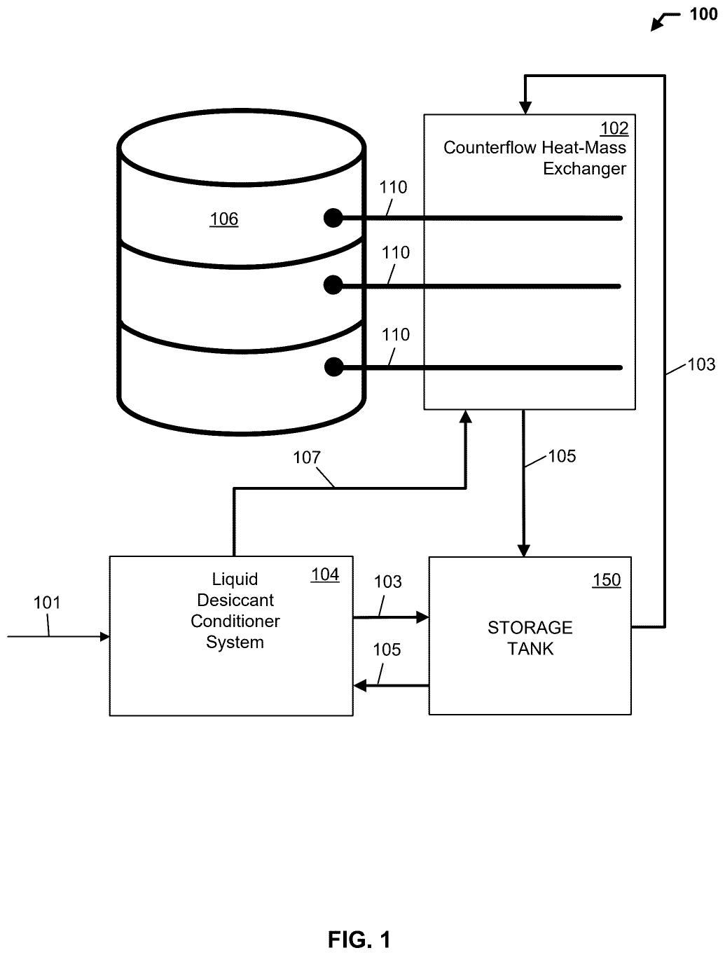

Referring to the drawings, FIG. 1 illustrates a heat exchanging system 100 that includes a heat and mass exchanger 102, a liquid desiccant conditioner system 104, a data center 106 (or other heat source that requires cooling), a storage tank 150, and multiple heat transfer tubes 110 thermally coupling the data center 106 to the heat and mass exchanger 102. Data center 106 may be any heat producing facility that may need cooling. For instance, data center 106 may house one or more computing devices, such as servers, that store and process data. For example, each computing device may include one or more processors (e.g., processing cores) that execute instructions to process data, and to store data within memory devices. The computing devices may generate heat as a result of processing data. The multiple heat transfer tubes 110 may be thermally coupled to the computing devices (e.g., to the processors), and may transfer the generated heat from the data center and into the heat and mass exchanger 102. For example, the heat transfer tubes 110 may be heat pipes. In some examples, a flow of heat transfer fluid, such as water or liquid desiccant, may flow through the heat transfer tubes 110. For instance, the heat transfer tubes 110 may provide the heat transfer fluid to and/or from a regenerator. In some examples, the heat transfer tubes 110 may not be a set of distinct tubes, but rather tubes that are internal to a plate, such as of a plate for a microchannel heat exchanger.

Further, the heat and mass exchanger 102 may receive low concentration liquid desiccant 103 from a storage tank 150 that stores low concentration liquid desiccant 103 that has been used by the liquid desiccant conditioner system 104. For example, the liquid desiccant conditioner system 104 may condition a flow of process air 101 (e.g., outside air), and may cool and dehumidify the flow of process air 101 to provide a flow of supply air 107. The liquid desiccant conditioner system 104 may dehumidify the flow of process air 101 using high concentration liquid desiccant 105 received from the storage tank 150. During the dehumidification process, the high concentration liquid desiccant 105 may absorb moisture (e.g., water) from the flow of process air 101. As a result, the high concentration liquid desiccant 105 is diluted with water, resulting in the low concentration liquid desiccant 103 that is provided back to the storage tank 150. The heat and mass exchanger 102 receives the low concentration liquid desiccant 103 from the storage tank 150.

As illustrated, each of the heat transfer tubes 110 may proceed into the heat and mass exchanger 102. The heat and mass exchanger 102 may receive the stream of supply air 107 from the liquid desiccant conditioner system 104, and may provide the stream of supply air 107 across the multiple heat transfer tubes 110. As the stream of supply air 107 flows across the heat transfer tubes 110, the stream of supply air 107 absorbs heat from the heat transfer tubes 110.

The heat and mass exchanger 102 provides the heated flow of air as exhaust air 109. For instance, the heat and mass exchanger 102 may provide the flow of exhaust air 109 to an outside environment. As such, the heat and mass exchanger 102 can serve to dissipate heat generated by the data center 106 to an outside environment.

Furthermore, the heat and mass exchanger 102 may contact (e.g., spray, drip, feed) the low concentration liquid desiccant 103 received from the liquid desiccant conditioner system 104 with one or more of the heat transfer tubes 110 and/or evaporative media. The flow of low concentration liquid desiccant 103 in the heat and mass exchanger 102 is in a direction that is counterflow to the direction of the stream of supply air 107 flowing across the heat transfer tubes 110. In other examples, the flow of the low concentration liquid desiccant 103 in the heat and mass exchanger 102 is in a direction that is crossflow to the direction of the stream of supply air 107 flowing across the heat transfer tubes 110.

In some embodiments, the storage tank 150 may house both high concentration liquid desiccant and low concentration liquid desiccant. Because of the differences in density, the high concentration liquid desiccant sinks to the bottom of the storage tank 150, while the low concentration liquid desiccant floats at the top of the storage tank.

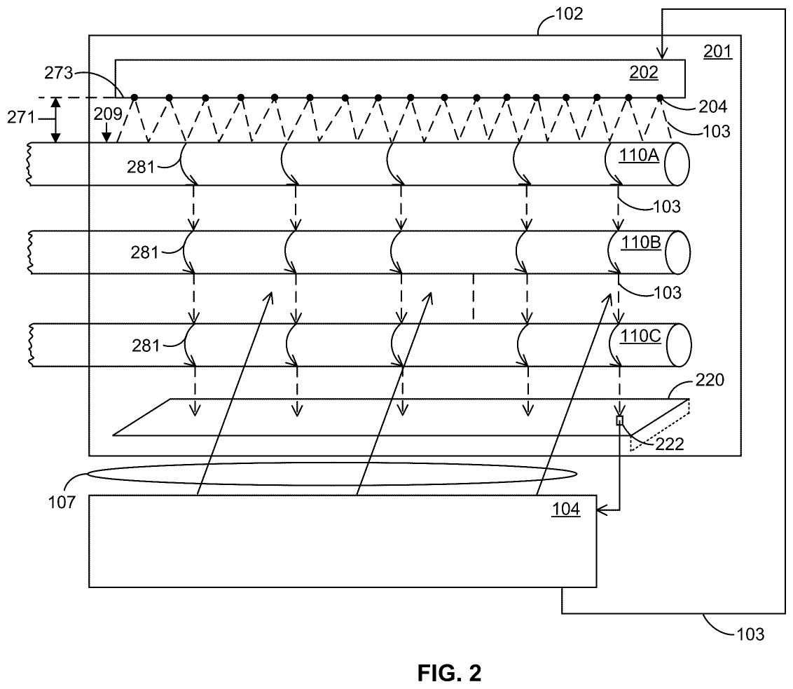

For example, as shown in FIG. 2 (described further below), the heat and mass exchanger 102 may spray (or drip) the low concentration liquid desiccant 103 onto an uppermost one of the heat transfer tubes 110 (e.g., 110A). The uppermost heat transfer tube 110A may dissipate heat (e.g., heat from the data center 106) through the heat transfer tube 110 to the low concentration liquid desiccant 103, causing the low concentration liquid desiccant 103 to evaporate water and thereby generate relatively higher concentration liquid desiccant. In examples, the low concentration liquid desiccant 103 may flow (e.g., fall, roll off) from the uppermost heat transfer tube 110 to one or more lower heat transfer tubes 110, each of which can also dissipate heat to the low concentration liquid desiccant 103.

The heat and mass exchanger 102 may capture (e.g., collect) the relatively higher concentration liquid desiccant, and provide the relatively higher concentration liquid desiccant as high concentration liquid desiccant 105 to the liquid desiccant conditioner system 104 (or return to the storage tank 150 as in FIG. 1). As such, in addition to dissipating heat from the data center 106, the heat and mass exchanger 102 may serve as a regenerator to regenerate the low concentration liquid desiccant 103.

FIG. 2 illustrates further details of the heat and mass exchanger 102. As illustrated, the heat and mass exchanger 102 includes a header 202, multiple heat transfer tubes 110A, 110B, 110C, and a collector 220 all within a housing 201. As described herein, the multiple heat transfer tubes 110A, 110B, 110C may transfer heat into the housing 201 from, for example, a data center 106.

The header 202 receives low concentration liquid desiccant 103 from the liquid desiccant conditioner system 104, and drips the low concentration liquid desiccant 103 onto the first heat transfer tube 110A (i.e., the uppermost heat transfer tube 110A). In some embodiments, as illustrated, the low concentration liquid desiccant 103 exits the header 202 through multiple header openings 204. The header 202 may include a sufficient number of header openings 204 to coat a top surface 209 of the heat transfer tube 110A. For example, the header 202 may be manufactured to have a number of header openings 204 based on a distance 271 between a bottom surface 273 of the header 202 and the top surface 209 of the heat transfer tube 210A.

The shorter the distance 271, the larger the number of header openings 204 that may be required to coat the top surface 209 of the heat transfer tube 210A.

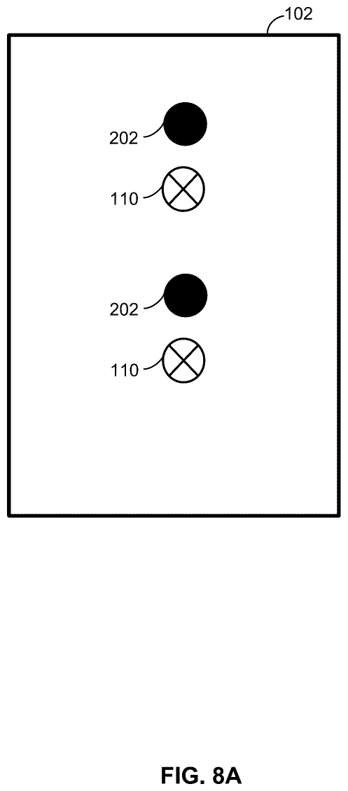

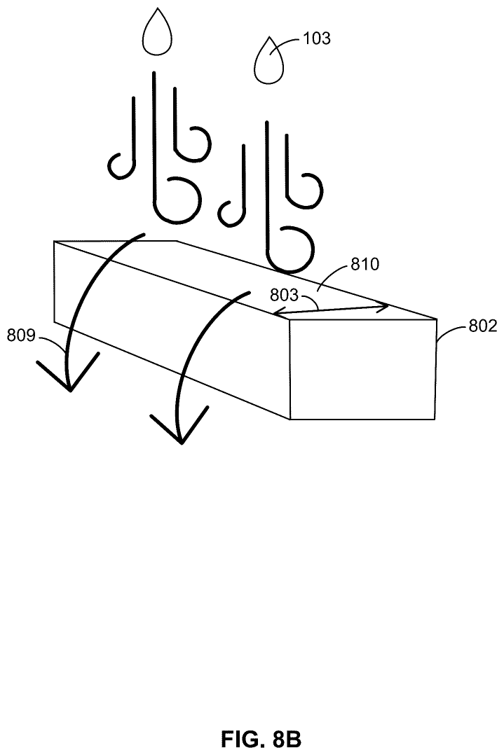

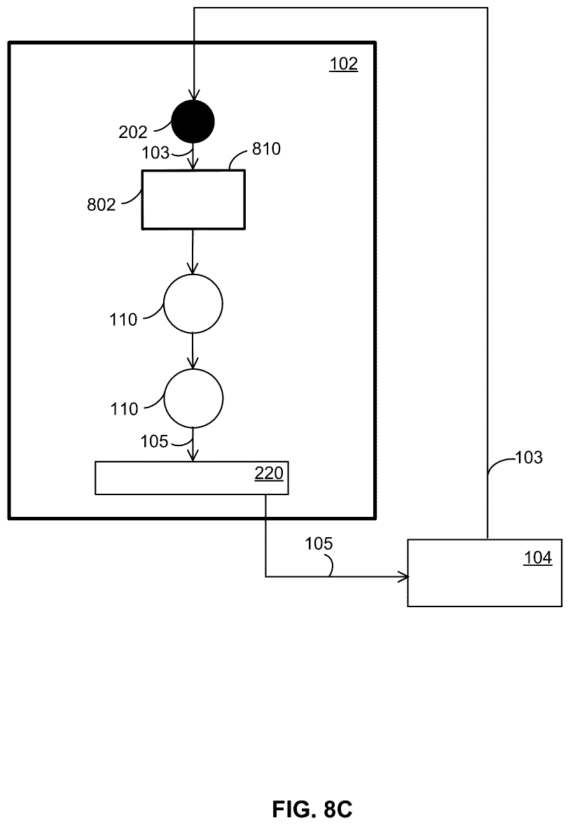

As illustrated by arrows 281, the low concentration liquid desiccant 103 may roll off of or around the heat transfer tube 210A and fall onto the heat transfer tube 210B below. Similarly, the low concentration liquid desiccant 103 may roll off of or around the heat transfer tube 210B and fall onto the heat transfer tube 210C. An example of an alternate geometry is shown in FIG. 8B. As described herein, the low concentration liquid desiccant 103 may absorb heat from one or more of the heat transfer tubes 210A, 210B, 210C as the low concentration liquid desiccant 103 makes contact with each heat transfer tube 210A, 210B, 210C. As a result, the low concentration liquid desiccant 103 may evaporate water, thereby generating high concentration liquid desiccant 105. The collector 220 may capture the high concentration liquid desiccant 105, and transfer the high concentration liquid desiccant 105 out of the heat and mass exchanger 102 through one or more collector openings 222.

As further illustrated, after flowing through the collector opening 222, the high concentration liquid desiccant 105 is provided to the liquid desiccant conditioner system 104 (or the storage tank 150 as in FIG. 1). As described herein, the liquid desiccant conditioner system 104 may use the high concentration liquid desiccant 105 to dehumidify a flow of process air. The used, and thus diluted, liquid desiccant is provided back to the heat and mass exchanger 102 as the low concentration liquid desiccant 103.

In addition, the housing 201 of the heat and mass exchanger 102 directs a flow of cool, dehumidified supply air 107, received from the liquid desiccant conditioner system 104, across the heat transfer tubes 210A, 210B, 210C, thereby removing further heat from the heat transfer tubes 210A, 210B, 210C. As such, the heat and mass exchanger 102 can not only dissipate heat from the heat transfer tubes 210A, 210B, 210C to remove heat from a facility, such as a data center 106, but can also regenerate low concentration liquid desiccant 103 as high concentration liquid desiccant 105 to allow a conditioning system, such as the liquid desiccant conditioner system 104, to dehumidify a flow of process air. As will be understood, for purposes of illustration in FIG. 2, the transfer of supply air 107 and liquid desiccant 103, 105 between the heat and mass exchanger 102 and the liquid desiccant conditioner system 104 has been simplified.

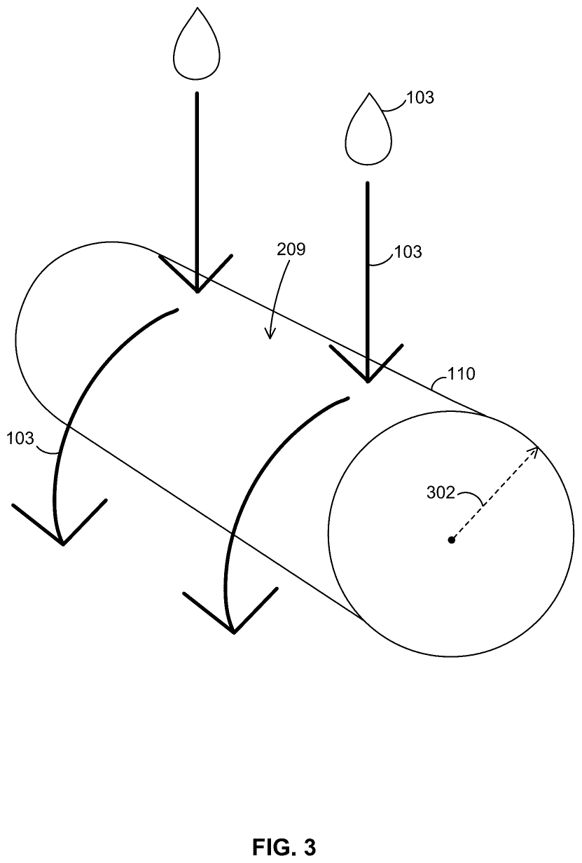

FIG. 3 illustrates portions of a heat transfer tube 110. As illustrated, the low concentration liquid desiccant 103 may fall onto the top surface 209 of the heat transfer tube 110, and may roll off of or around the heat transfer tube 110. In this example, the heat transfer tube 110 is cylindrical in shape. For example, the heat transfer tube 110 may have a radius 302 in the range from 1/16^{th} inch to 1 inch. In some examples, the heat transfer tube 110 may be a heat pipe that is made of metal, such as copper or aluminum, or any other suitable heat conducting material. The heat from the data center 106 can be provided to the interior of the heat transfer tube 110 in the form of a heat transfer liquid.

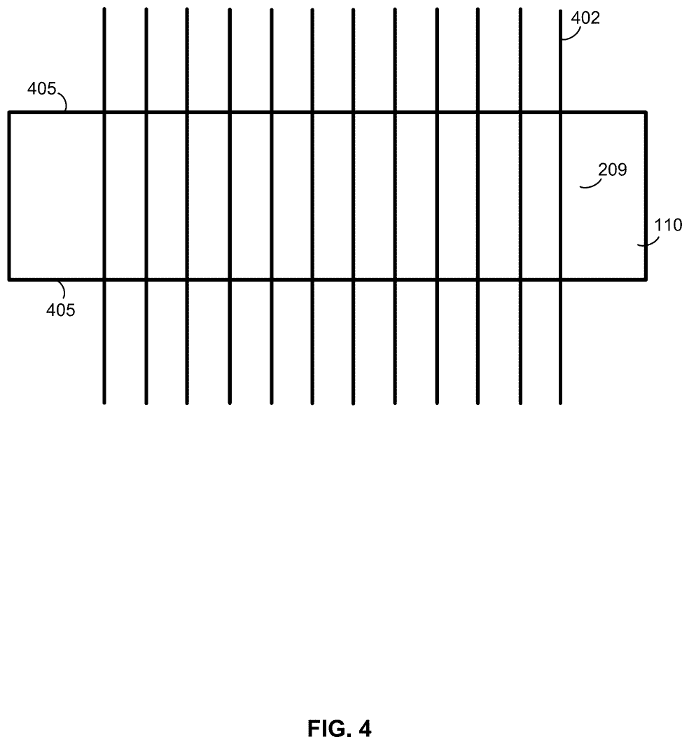

FIG. 4 illustrates a top or side view of a heat transfer tube 110 in contact with a plurality of fins 402. The fins 402 may be made of metal, such as copper or aluminum, or any other suitable heat conducting material. The fins 402 increase the surface area for liquid desiccant and supply air to contact one another, while also allowing a relatively higher conductivity pathway from the heat transfer tube 110 to the liquid desiccant. As illustrated, the fins 402 are parallel to each other and run perpendicular to a length of the heat transfer tube 110. The fins 402 can be positioned in arrangements that increase thermal transfer from the heat transfer tube 110 to the fins 402. For instance, in some examples, the fins 402 are positioned on the top surface 209 of the heat transfer tube 110. In other examples, the fins 402 are attached to either side 405 of the heat transfer tube 110 and extend out from the sides 405 of the heat transfer tube 110. In yet other examples, the heat transfer tube 110 passes through an opening (e.g., a hole) in the fins 402. In other words, the heat transfer tube 110 may pass through a center opening of each fin 402. Each fin 402 may then be securely attached to the heat transfer tube 110 using an attachment mechanism, such as a bracket, glue, a weld, etc. In some instances, the heat transfer tube 110 and/or the fins 402 are coated with a hydrophilic material.

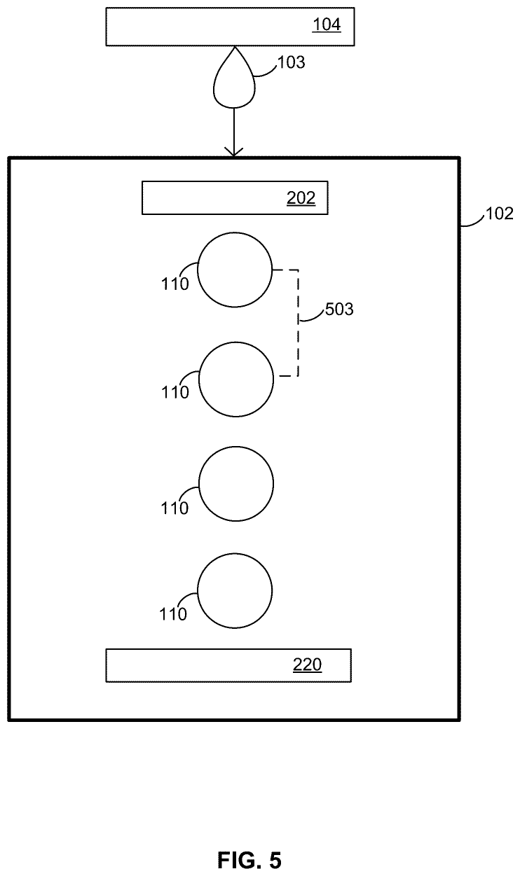

FIG. 5 illustrates a heat and mass exchanger 102 with multiple heat transfer tubes 110 that are cylindrical in shape. As illustrated, the heat transfer tubes 110 can be run in series with respect to the flow of the low concentration liquid desiccant 103, which may allow for more effective heat transfer from the heat transfer tubes 110 to the low concentration liquid desiccant 103. Specifically, each heat transfer tube 110 is vertically distanced from one or more adjacent heat transfer tubes 110 by a predetermined distance 503. The predetermined distance 503 may be in the range from 0.5 inches to 6 inches.

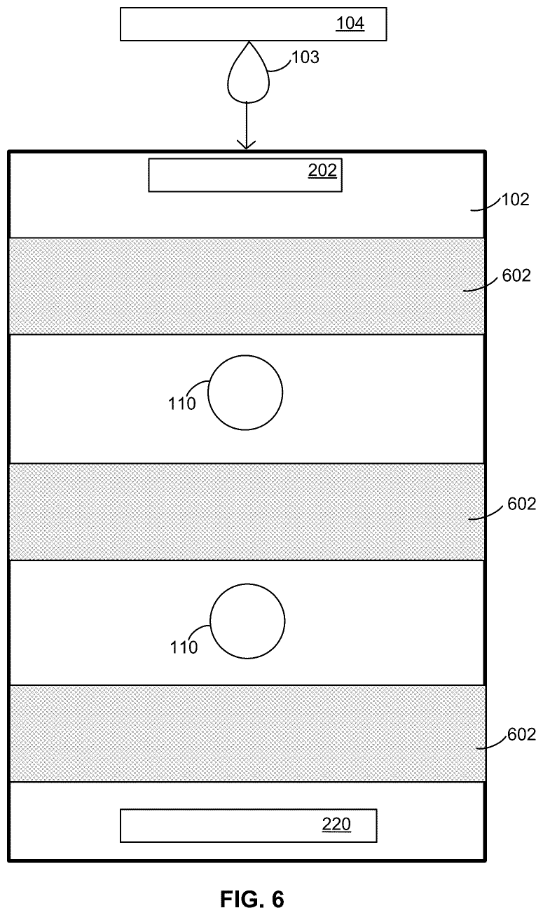

In the example of FIG. 6, the heat and mass exchanger 102 includes evaporative media 602, such as wicking material (e.g., CELdek® media), below the header 202 as well as between each heat transfer tube 110. The evaporative media 602 may slow the downward flow of the ow concentration liquid desiccant 103, which can increase moisture removal as the low concentration liquid desiccant 103 proceeds down through the heat and mass exchanger 102.

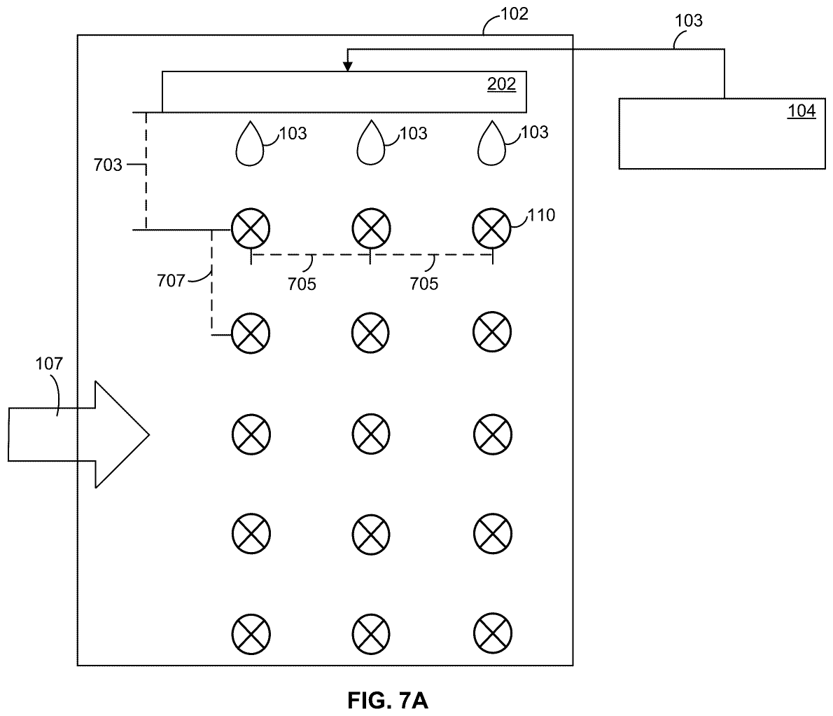

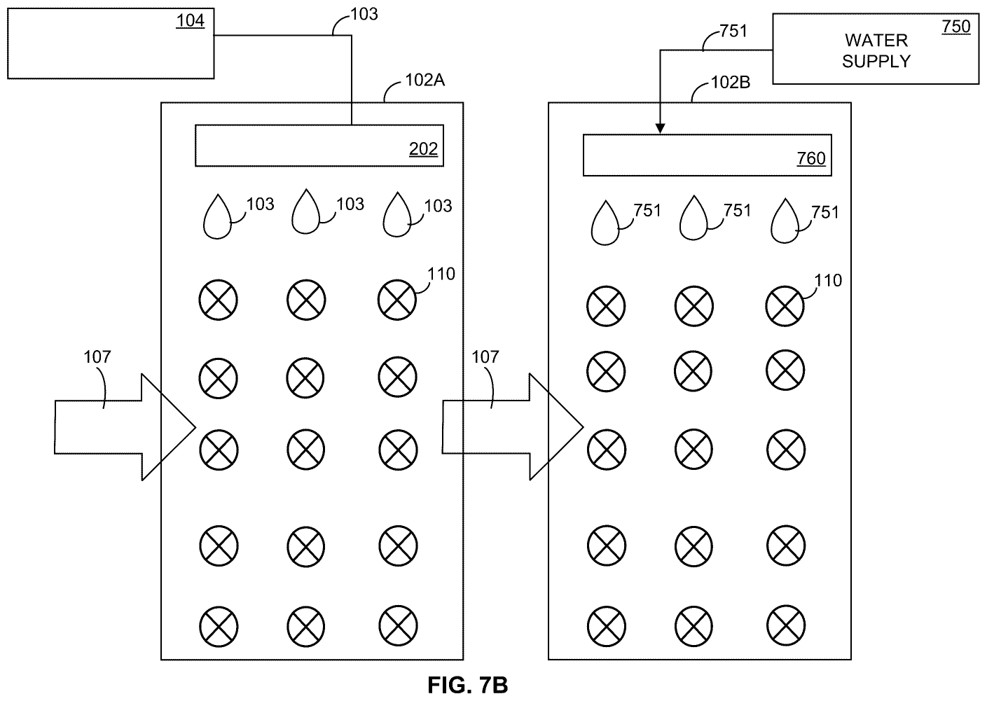

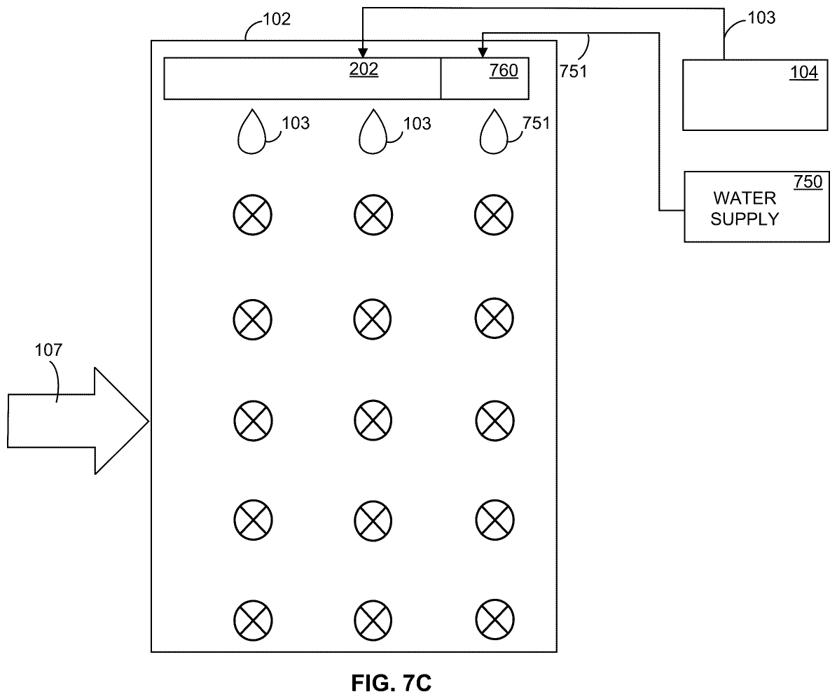

FIG. 7A illustrates heat and mass exchanger 102 with several rows of heat transfer tubes 110. In this configuration, the flow of supply air 107 passes through, and can absorb heat from, several rows of heat transfer tubes 110. In addition, each heat transfer tube 110 is horizontally offset from at least another heat transfer tube 110 by a first predetermined distance 705. In addition, each heat transfer tube 110 is vertically offset from at least another heat transfer tube by a second predetermined distance 707. Moreover, the point at which the low concentration liquid desiccant 103 is released from the header 202 is a third predetermined distance 703 from the uppermost row of heat transfer tubes 110. The header 202 is configured to deliver the low concentration liquid desiccant 103 received from the liquid desiccant conditioner system 104 to each row of heat transfer tubes 110. The first predetermined distance 705 may be in the range from 0.5 inches to 6 inches. The second predetermined distance 707 may be in the range from 0.5 to 6 inches. Further, the third predetermined distance 703 may be in the range from 0 to 3 inches (e.g., 1.5 inches).

The example of FIG. 7B includes a first heat and mass exchanger 102A that is similar to the heat and mass exchanger 102 of FIG. 7A, but further includes a second heat and mass exchanger 102B. As illustrated, the flow of supply air 107 proceeds across the heat transfer tubes 110 of the first heat and mass exchanger 102A, and then proceeds across the heat transfer tubes 110 of the second heat and mass exchanger 102B. The second heat and mass exchanger 102B, rather than receiving low concentration liquid desiccant 103 from the liquid desiccant conditioner system 104, includes a header 760 that receives water 751 from a water supply 750 (e.g., city water supply), and delivers the water 751 to the rows of heat transfer tubes 110. The water 751 may dissipate further heat from the heat transfer tubes 110. This allows for better cooling of the data center 106, because the water in the second heat and mass exchange 102B will evaporate at a lower temperature than the liquid desiccant in the first heat and mass exchanges 102A due to the higher ion concentration in the liquid desiccant. The change in the direction of the flow of supply air 107 from up through the heat and mass exchanger (e.g., FIGS. 1 and 2 use a counter-flow arrangement) to across the heat and mass exchangers 102A, 102B helps enable this approach.

FIG. 7C illustrates an example where the heat and mass exchanger 102 receives low concentration liquid desiccant 103 from the liquid desiccant conditioner system 104, and water 751 from a water supply 750. In this example, the heat and mass exchanger 102 includes a first header 202 that is configured to receive the low concentration liquid desiccant 103, and a second header 760 that is configured to receive the water 751. The first header 202 delivers the low concentration liquid desiccant 103 to one or more columns of the heat transfer tubes 110, and the second header 760 delivers the water 751 to one or more columns of the heat transfer tubes 110. For example, the first header 202 may spray the low concentration liquid desiccant 103 over the first and second columns of heat transfer tubes 110, and the second header 760 may spray the water 751 over the third column of heat transfer tubes. In this configuration, the flow of supply air 107 passes first through the one or more columns of heat transfer tubes 110 sprayed with the low concentration liquid desiccant 103, and then passes through the one or more columns of heat transfer tubes 110 sprayed with the water 751. In other words, the one or more columns of heat transfer tubes 110 sprayed with the water 751 are downstream the one or more columns of heat transfer tubes 110 sprayed with the low concentration liquid desiccant 103. In other examples, the heat and mass exchanger 102 may direct the flow of supply air 107 first across the one or more heat transfer tubes 110 sprayed with water 751, and then across the one or more heat transfer tubes 110 sprayed with low concentration liquid desiccant 103.

In the embodiments of FIGS. 7A to 7C, the heat transfer tubes 110 can be arranged in a number of columns. This allows liquid desiccant from one row to drip down onto another heat transfer tube 110 in the row below. However, alternate arrangements may be employed in other embodiments. For example, when an evaporative media is employed, the heat transfer tubes 110 may or may not be arranged in columns.

FIG. 8A illustrates heat and mass exchanger 102 with multiple rows of headers 202 positioned over corresponding heat transfer tubes 110. Each of the multiple headers 202 are configured to deliver low concentration liquid desiccant 103 to a corresponding one of the heat transfer tubes 110. As illustrated, the headers 202 are vertically offset from each other. Although for simplicity one heat transfer tube 110 is illustrated below each header 202, in other examples, multiple heat transfer tubes 110 may be positioned below each header 202. As described herein, each header 202 may deliver the low concentration liquid desiccant 103 to a corresponding uppermost heat transfer tube 110 (i.e., the heat transfer tube 110 immediately below the header 202), and the low concentration liquid desiccant 103 may flow from the upper most heat transfer tube 110 to other heat transfer tubes 110 below.

FIG. 8B illustrates a heat transfer tube 802 that may be rectangular in shape or otherwise have a flat or generally flat upper surface. The heat transfer tube 802 may have a top surface 810 with a width 803 in the range of 1/4^{th} inch to 3 inches, for example. A header 202 may spray low concentration liquid desiccant 103 onto the top surface 810 of the heat transfer tube 802, and the low concentration liquid desiccant 103 may absorb heat from the heat transfer tube 802 (e.g., the fluid inside of the heat transfer tube 802). Further, the low concentration liquid desiccant 103 may roll off of or around the top surface 810, as indicated by arrows 809. The heat transfer tube 802 can be substituted for any of the heat transfer tubes 110 described herein, such as within the heat exchanging system 100.

For example, FIG. 8C illustrates the heat and mass exchanger 102 with a rectangular heat transfer tube 802 and multiple cylindrical heat transfer tubes 110. In this example, the header 202 can spray low concentration liquid desiccant 103 onto the top surface 810 of the rectangular heat transfer tube 802. The low concentration liquid desiccant 103 may roll off of the top surface 810, and fall onto the uppermost cylindrical heat transfer tube 110. Similarly, the low concentration liquid desiccant 103 may roll off of the uppermost cylindrical heat transfer tube 110, and fall onto the cylindrical heat transfer tube 110 immediately below. As the low concentration liquid desiccant 103 contacts each of the heat transfer tubes 802, 110, heat is absorbed, thereby evaporating moisture from the low concentration liquid desiccant 103 to generate high concentration liquid desiccant 105. The collector 220 captures the high concentration liquid desiccant 105, and can deliver the high concentration liquid desiccant 105 to a liquid desiccant conditioner system 104 (or the storage tank 150).

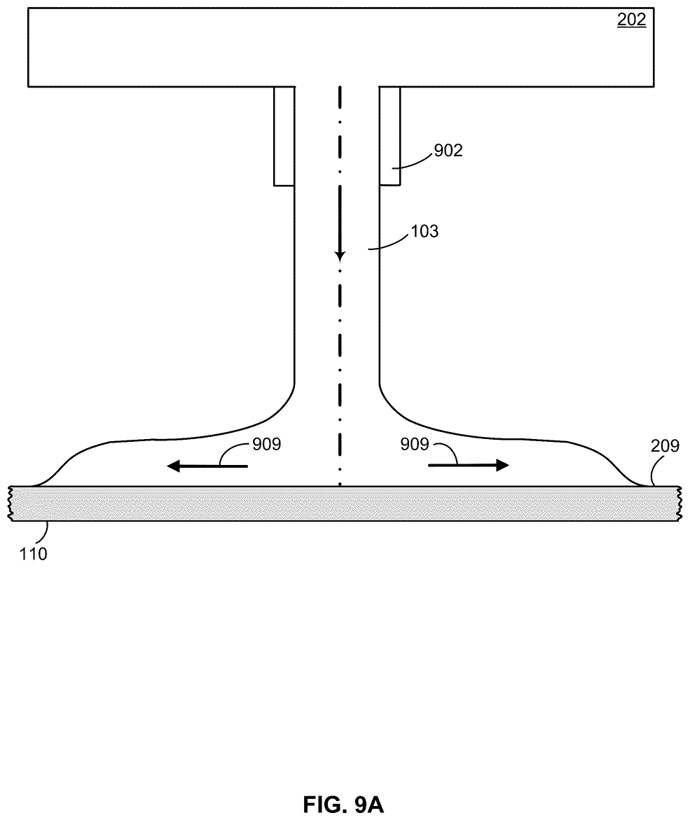

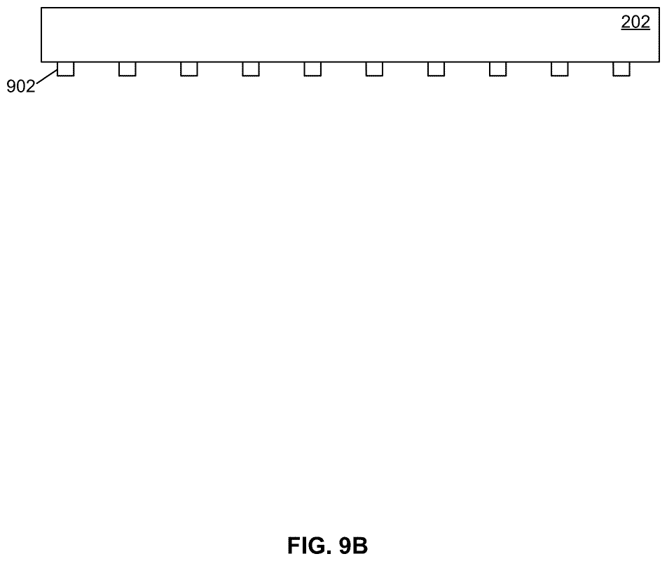

FIG. 9A illustrates a cross-sectional view of a header 202 that includes one or more nozzles 902, such as a high-pressure nozzle. The nozzle 902 is configured to deliver a jet stream of low concentration liquid desiccant 103 to a surface 209 of a heat transfer tube 110 (e.g., a jet impingement process). As illustrated, as the low concentration liquid desiccant 103 contacts the surface 209, the low concentration liquid desiccant 103 spreads along the surface 209 as indicated by arrows 909. The nozzle 902 may be configured to deliver a jet stream of the low concentration liquid desiccant 103. FIG. 9B illustrates a side view of the header 202 illustrating multiple nozzles 902 along a length of the header 202. In this configuration of FIGS. 9A and 9B, the flat surface 209 of the heat transfer tube 110 provides a surface for the low concentration liquid desiccant 103 to contact before, for example, rolling off of the surface 209 and contacting another heat transfer tube 110. As a result, the low concentration liquid desiccant 103 enters a jet impingement flow regime which is highly favorable for increased heat transfer rates from the heat transfer tube 110 to the low concentration liquid desiccant 103.

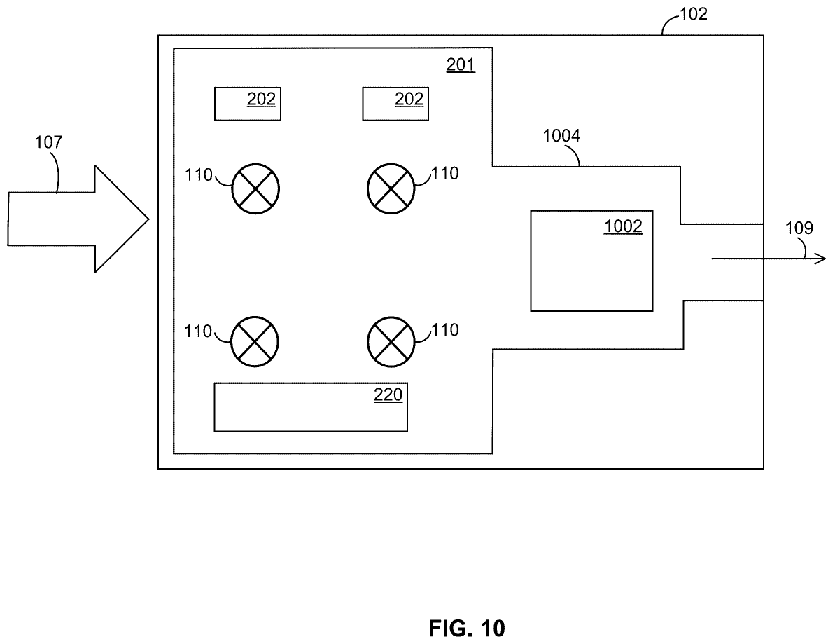

FIG. 10 illustrates the heat and mass exchanger 102 with a precipitated liquid desiccant collector 1002 positioned downstream of the heat transfer tubes 110. For instance, the precipitated liquid desiccant collector 1002 may be positioned within an exhaust air duct 1004 of the heat and mass exchanger 102. The precipitated liquid desiccant collector 1002 is configured to precipitate liquid desiccant out from the flow of exhaust air 109, and provide the collected liquid desiccant to the collector 220. The precipitated liquid desiccant collector 1002 may be a precipitator (e.g., electrostatic precipitator, wet electrostatic precipitator), or a tortious path precipitator, for example. The addition of the precipitated liquid desiccant collector 1002 may facilitate precipitation of entrained liquid desiccant that otherwise may flow out with the flow of exhaust air 109. Although, in this example, the heat and mass exchanger 102 is illustrated horizontally with the flow of supply air 107 entering the left side of the heat and mass exchanger 102 and the flow of exhaust air 108 exiting from the right side of the heat and mass exchanger 102, other configurations are contemplated. For instance, in other examples, the flow of supply air 107 may enter from another side of the heat and mass exchanger 102, and the flow of exhaust air 109 may flow out from another side of the heat and mass exchanger 102 (e.g., as illustrated in FIG. 1).

Among other advantages, the embodiments can allow for heat removal from a facility, such as a data center, using a flow of supply air from a conditioning system, while at the same time using the removed heat to regenerate a low concentration fluid, such as liquid desiccant, received from the conditioning system, and can provide the regenerated fluid back to the conditioning system.

For instance, in some examples, a heat-mass exchanger includes a housing configured to receive a flow of supply air cooled and dehumidified by a liquid desiccant conditioner system. The heat-mass exchanger also includes a header configured to receive low concentration liquid desiccant from the liquid desiccant conditioner system, and feed the low concentration liquid desiccant onto one or more heat transfer tubes within the housing. The one or more heat transfer tubes are configured to dissipate heat to the liquid desiccant to generate relatively higher concentration desiccant. Further, the heat-mass exchanger includes a collector that is configured to capture the higher concentration desiccant, and feed the higher concentration desiccant to the liquid desiccant conditioner system. The liquid desiccant conditioner system may use the higher concentration desiccant to dehumidify a flow of process air, for example.

The various embodiments described above are provided by way of illustration only and should not be construed to limit the claims attached hereto. Those skilled in the art will readily recognize various modifications and changes that may be made without following the example embodiments and applications illustrated and described herein, and without departing from the spirit and scope of the following claims.

What is claimed is:

1. A heat-mass exchanger, comprising:
a housing configured to receive a flow of supply air cooled and dehumidified by a liquid desiccant conditioner system;
a header configured to feed desiccant onto at least one heat transfer tube within the housing, the at least one heat transfer tube configured to dissipate heat to the desiccant to generate relatively higher concentration desiccant; and
a collector configured to capture the higher concentration desiccant and feed the higher concentration desiccant to the liquid desiccant conditioner system.

2. The heat-mass exchanger of claim 1, wherein the heat is transferred from the at least one heat transfer tube to the desiccant to evaporate water off into the flow of supply air and form exhaust air.

3. The heat-mass exchanger of claim 1, wherein the liquid desiccant conditioner system is configured to feed the higher concentration desiccant to a conditioning channel to dehumidify a flow of process air.

4. The heat-mass exchanger of claim 3, wherein the flow of supply air comprises the dehumidified flow of outside air.

5. The heat-mass exchanger of claim 1, wherein the at least one heat transfer tube is coupled to a data center.

6. The heat-mass exchanger of claim 1 comprising a plurality of heat sink fins coupled to the at least one heat transfer tube.

7. The heat-mass exchanger of claim 1, wherein the header is configured to receive the desiccant from the liquid desiccant conditioner system.

8. The heat-mass exchanger of claim 1, wherein the desiccant fed onto the at least one heat transfer tube is low concentration.

9. The heat-mass exchanger of claim 1, wherein the at least one heat transfer tube comprises at least two heat transfer tubes, wherein the at least two heat transfer tubes enter the housing vertically offset from each other by a predetermined distance.

10. The heat-mass exchanger of claim 1, wherein the housing is configured to direct the flow of supply air to the at least one heat transfer tube, the at least one heat transfer tube configured to dissipate heat to the flow of supply air.

11. The heat-mass exchanger of claim 1, wherein the header comprises one or more nozzles configured to spray the desiccant onto the at least one heat transfer tube.

12. The heat-mass exchanger of claim 11, wherein the at least one heat transfer tube comprises a first heat transfer tube that is rectangular in shape, and the one or more nozzles are configured to spray the desiccant across a flat upper surface of the first heat transfer tube.

13. The heat-mass exchanger of claim 11, wherein the at least one heat transfer tube comprises a first heat transfer tube and a second transfer tube, and the one or more nozzles comprise a first row of nozzles and a second row of nozzles, and wherein the first row of nozzles is vertically offset from the first heat transfer tube and configured to spray the desiccant onto the first heat transfer tube, and the second row of nozzles is vertically offset from the second heat transfer tube and configured to spray the desiccant onto the second heat transfer tube.

14. The heat-mass exchanger of claim 1, wherein the at least one heat transfer tube is a heat pipe.

15. The heat-mass exchanger of claim 1, wherein the at least one heat transfer tube is thermally coupled to at least one processor.

16. A data center cooling system comprising:
a liquid desiccant conditioning system; and
a heat-mass exchanger comprising:
a housing configured to receive a flow of supply air from the liquid desiccant conditioner system;
a header configured to receive desiccant from the liquid desiccant conditioner system and feed the desiccant onto at least one heat transfer tube within the housing, the at least heat transfer tube configured to dissipate heat to the desiccant to generate relatively higher concentration desiccant; and
a collector configured to capture the higher concentration desiccant and feed the higher concentration desiccant to the liquid desiccant conditioner system to dehumidify a flow of outside air.

17. A heat-mass exchanger, comprising:
a housing configured to receive a flow of supply air cooled and dehumidified by a liquid desiccant conditioner system;
a first header configured to feed desiccant onto at least a first heat transfer tube within the housing, the at least first heat transfer tube configured to dissipate heat to the desiccant to generate relatively higher concentration desiccant;
a collector configured to capture the higher concentration desiccant and feed the higher concentration desiccant to the liquid desiccant conditioner system; and
a second header configured to feed water onto at least a second heat transfer tube within the housing.

18. The heat-mass exchanger of claim 17, wherein the housing is configured to divert the flow of supply air across the at least first heat transfer tube and then the at least second heat transfer tube.

19. The heat-mass exchanger of claim 17, wherein the at least first heat transfer tube comprises a first plurality of heat transfer tubes vertically offset from each other, and the at least second heat transfer tube comprises a second plurality of heat transfer tubes vertically offset from each other.

20. The heat-mass exchanger of claim 19, wherein the first header is configured to feed the desiccant onto a top one of the first plurality of heat transfer tubes, and wherein the second header is configured to feed the water onto a top one of the second plurality of heat transfer tubes.
